(19) United States
(12) Patent Application Publication
(10) Pub. No.: US 2025/0364382 A1
(43) Pub. Date: Nov. 27, 2025

(54) SEMICONDUCTOR DEVICE

(71) Applicant: FUJI ELECTRIC CO., LTD., Kawasaki-shi (JP)

(72) Inventors: Ryo NOMAGUCHI, Kawasaki-shi (JP); Takahito HARADA, Kawasaki-shi (JP)

(73) Assignee: FUJI ELECTRIC CO., LTD., Kawasaki-shi (JP)

(21) Appl. No.: 19/092,345

(22) Filed: Mar. 27, 2025

(30) Foreign Application Priority Data
May 23, 2024 (JP) 2024-083752

(51) Int. Cl. H01L 23/498; H01L 25/065; H02M 1/32; H02M 7/00; H10D 80/20

(52) U.S. Cl. CPC H01L 23/49805; H01L 23/49811; H01L 25/0655; H02M 7/003; H10D 80/251; H02M 1/327

(57) ABSTRACT

A semiconductor device, including: a substrate having a mounting surface; a semiconductor element mounted on the mounting surface of the substrate; and a positive electrode terminal and a negative electrode terminal disposed on the substrate. Each of the positive electrode terminal and the negative electrode terminal has at least one rising portion, to thereby have a total of at least three rising portions, each extending in a plane that intersects the mounting surface of the semiconductor element. Each of the rising portion of the positive electrode terminal faces one of the rising portions of the negative electrode terminal in a first direction.

### CROSS-REFERENCE TO RELATED APPLICATION

This application is based upon and claims the benefit of priority to Japanese Patent Application No. 2024-083752, filed on May 23, 2024, the entire contents of which are incorporated herein by reference.

### BACKGROUND OF THE INVENTION

### 1. Technical Field

The present invention relates to a semiconductor device including a positive electrode terminal and a negative electrode terminal.

### 2. Description of the Related Art

Conventionally, a semiconductor device has a circuit board on which a semiconductor element is mounted, and is used in an inverter device or the like. In such a semiconductor device, a main terminal connected to an external conductor, such as a positive electrode terminal or a negative electrode terminal disposed on one side of a substrate, is disposed (see, for example, JP 2013-098425 A, JP 2021-120975 A, WO 2020/170553 A, WO 2018/142863 A, and Bodo's Power Systems (March 2024, p.26-30)).

### SUMMARY OF THE INVENTION

In the semiconductor device, in order to suppress generation of a surge voltage, it is conceivable to increase the mutual inductance at the time of switching in a manner of increasing the facing area by vertically overlapping the positive electrode terminal and the negative electrode terminal. However, when the facing area between the positive electrode terminal and the negative electrode terminal increases, the mounting area increases. Since it is not possible to provide a wiring immediately below the positive electrode terminal and the negative electrode terminal, pattern layout on the substrate is restricted.

An object of the present invention is to provide a semiconductor device capable of increasing a mutual inductance while suppressing an increase in a mounting area of a positive electrode terminal and a negative electrode terminal.

According to an aspect, a semiconductor device includes a semiconductor element, a substrate on which the semiconductor element is mounted, and a positive electrode terminal and a negative electrode terminal disposed on a first side side extending in a first direction of the substrate. Each of the positive electrode terminal and the negative electrode terminal has a rising portion extending in a direction intersecting a mounting surface of the semiconductor element on the substrate, and three or more rising portions of the positive electrode terminal in total and three or more rising portions of the negative electrode terminal in total are located to be arranged and face each other.

According to the above aspect, it is possible to increase the mutual inductance while suppressing an increase in the mounting area of the positive electrode terminal and the negative electrode terminal.

### BRIEF DESCRIPTION OF THE DRAWINGS

FIG. 1 is a plan view illustrating a semiconductor device according to an embodiment;

FIG. 2 is a plan view illustrating a positive electrode terminal and a negative electrode terminal in the embodiment;

FIG. 3 is a perspective view illustrating the positive electrode terminal and the negative electrode terminal in the embodiment;

FIG. 4 is a left side view illustrating the positive electrode terminal and the negative electrode terminal in the embodiment;

FIG. 5 is a top perspective view illustrating a positive electrode terminal and a negative electrode terminal in a modification example of the embodiment;

FIG. 6 is a left side perspective view illustrating the positive electrode terminal and the negative electrode terminal in the modification example of the embodiment;

FIG. 7 is a perspective view illustrating a positive electrode terminal and a negative electrode terminal in a comparative example; and

FIG. 8 is an explanatory view for describing a mounting space and a facing area in the embodiment and the comparative example.

### DETAILED DESCRIPTION

A semiconductor device according to an embodiment of the present invention will be described below with reference to the drawings. The present invention is not limited to the embodiment described below, and can be appropriately modified and implemented within the scope not changing the gist thereof.

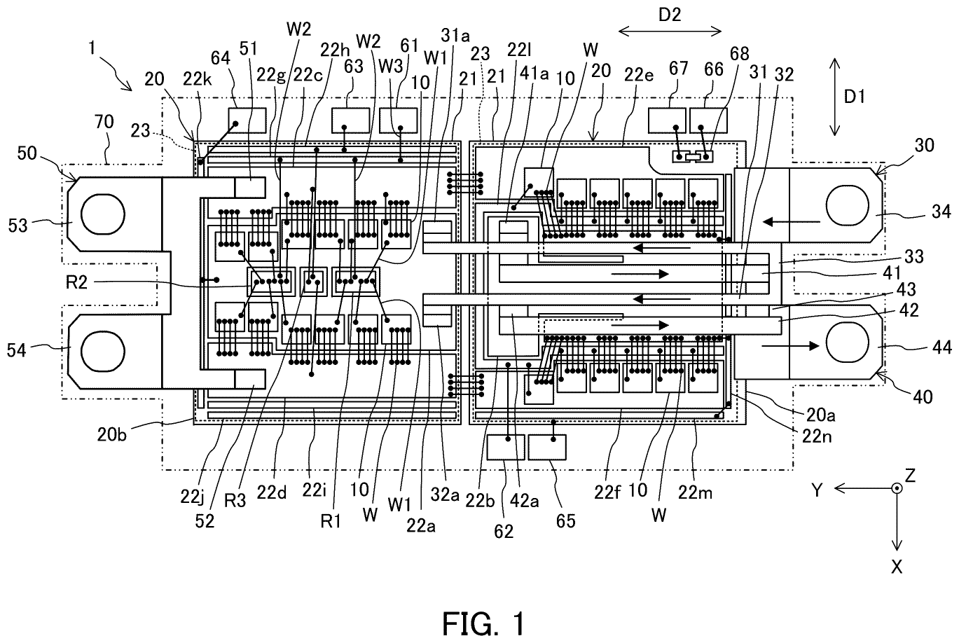

FIG. 1 is a plan view illustrating a semiconductor device 1 according to an embodiment.

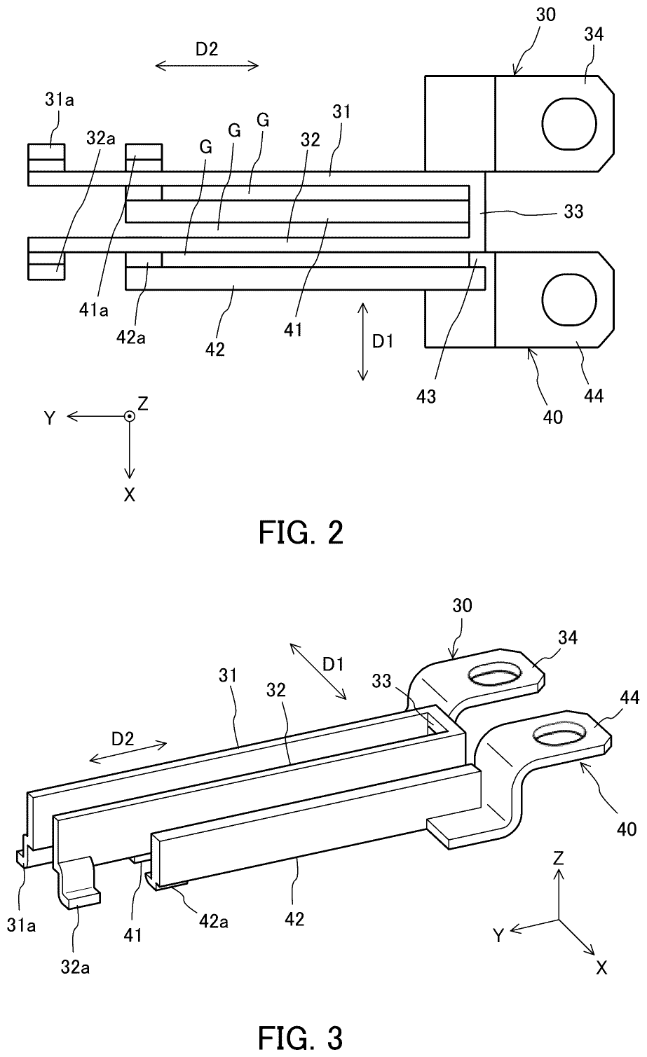

FIGS. 2 to 4 are a plan view, a perspective view, and a left side view illustrating a positive electrode terminal 30 and a negative electrode terminal 40 in the embodiment.

Regarding an X-direction, a Y-direction, and a Z-direction illustrated in FIGS. 1 to 4 and FIGS. 5 to 7 which will be described later, a thickness direction of a semiconductor element 10 is defined as the Z-direction, and, among the X-direction and the Y-direction that are perpendicular to the Z-direction and are perpendicular to each other, a first direction D1 in which a first side 20a of a multilayer substrate 20 on which the positive electrode terminal 30 and the negative electrode terminal 40 are disposed extends is defined as the X-direction. In some cases, the respective directions may be referred on the assumption that an X-direction positive side is a forward direction, an X-direction negative side is a backward direction, a Y-direction positive side is a leftward side, a Y-direction negative side is a rightward side, a Z-direction positive side is an upward side, and a Z-direction negative side is a downward side. Such directional terms are used for convenience of description. Thus, depending on the posture of the semiconductor device 1, the correspondence relationship with the X, Y, and Z-directions varies.

The semiconductor device 1 illustrated in FIG. 1 includes a plurality of semiconductor elements 10, a multilayer substrate 20, a positive electrode terminal 30, a negative electrode terminal 40, an output terminal 50, control terminals 61 to 63 and 65, a sensing terminal 64, temperature sensing terminals 66 and 67, a temperature sensing unit 68, a case 70 (illustrated by a two-dot chain line), a wiring W (including first to third control wirings W1 to W3), and first to third relay portions R1 to R3. In FIG. 1, only some of the wirings W are denoted by reference numerals.

As an example, the semiconductor device 1 is applied to a power conversion device such as an inverter device of an industrial or in-vehicle motor together with a cooler (not illustrated) disposed below the multilayer substrate 20. In the following description, detailed description of the same or similar known configuration, function, operation, assembly method, and the like as those of the semiconductor device 1 will be omitted.

A plurality of semiconductor elements 10 are mounted on each of a first circuit pattern 22a, a fifth circuit pattern 22e, and a sixth circuit pattern 22f of the multilayer substrate 20 by, for example, a conductive bonding material (not illustrated) such as solder.

A switching element of the semiconductor element 10 may include, for example, a SiC metal oxide semiconductor field effect transistor (MOSFET), a bipolar junction transistor (BJT), or the like. Furthermore, a diode element of the semiconductor element 10 may include, for example, a SiC schottky barrier diode (SBD), a junction barrier schottky (JBS) diode, a merged PN schottky (MPS) diode, a PN diode, or the like. The semiconductor element 10 may include, for example, a reverse conducting (RC)-insulated gate bipolar transistor (IGBT) element obtained by integrating an element such as an IGBT that is a switching element and a diode element such as a free wheeling diode (FWD) element or the like connected to the IGBT element and the switching element in an inverse parallel manner. This type of semiconductor element 10 is provided with electrodes (not illustrated) on the lower surface and the upper surface, is connected to a circuit layer of the multilayer substrate 20 on the lower surface by bonding, and is connected to the wiring W on the electrode provided on the upper surface. The wiring W is a metallic bonding wire, but may be replaced with, for example, a lead formed by processing a metal plate such as a copper plate. In the present specification, “connection” includes electrical connection.

The multilayer substrate 20 is an example of a substrate on which the semiconductor element 10 is mounted. The multilayer substrate 20 includes an insulating substrate 21, circuit layers (first to 14th circuit patterns 22a to 22n), and a heat dissipation layer 23 (not illustrated). The multilayer substrate 20 is, for example, a direct copper bonding (DCB) substrate or an active metal brazing (AMB) substrate, and has a rectangular shape in plan view.

The insulating substrate 21 may be, for example, a ceramic substrate formed of a ceramic material such as aluminum oxide (Al₂O₃), aluminum nitride (AlN), silicon nitride (Si₃N₄), or a composite material of aluminum oxide (Al₂O₃) and zirconium oxide (ZrO₂). The insulating substrate 21 may be, for example, a substrate obtained by molding an insulating resin such as epoxy resin, a substrate obtained by impregnating a base material such as a glass fiber with an insulating resin, a substrate obtained by coating a surface of a flat plate-shaped metal core with an insulating resin, or the like. In the example of FIG. 1, the insulating substrate 21 is provided to be divided into two pieces on the Y-direction positive side and the Y-direction negative side, but these insulating substrates 21 may be provided integrally. In addition, FIG. 1 illustrates a set of semiconductor units including the semiconductor element 10, the multilayer substrate 20, the positive electrode terminal 30, the negative electrode terminal 40, the output terminal 50, and the like, but, for example, three sets of semiconductor units constituting a three-phase inverter circuit may be disposed in the semiconductor device 1. As described above, the number of semiconductor elements 10 and multilayer substrates 20 is not particularly limited.

The heat dissipation layer 23 provided on the lower surface of the insulating substrate 21 is a member that functions as a heat conduction member that conducts heat generated in an inverter circuit to a cooler of copper or the like, and may be referred to as a heat dissipation plate, a conductor pattern, a heat dissipation pattern, or the like. The heat dissipation layer 23 is formed of, for example, a metal plate or a metal foil such as copper or aluminum. In FIG. 1, the heat dissipation layer 23 is indicated by a broken line because the heat dissipation layer 23 is hidden and does not appear by the insulating substrate 21. The cooler includes, for example, a metal plate (heat sink) made of copper, and is attached to a water jacket. The cooler includes a fin that dissipates heat to a coolant flowing in the water jacket. The heat dissipation layer 23 of the multilayer substrate 20 is connected to the upper surface of a metal plate of the cooler by a bonding material such as solder.

The circuit layer including the first to 14th circuit patterns 22a to 22n is provided on the upper surface of the insulating substrate 21. Although each of the circuit patterns 22a to 22n will be described later, the circuit layer is a member that function as a wiring member in the inverter circuit and are formed by, for example, a metal plate, a metal foil, or the like of copper, aluminum, or the like. The circuit layer (first to 14th circuit patterns 22a to 22n) may be referred to as a conductor layer, a conductive layer, a conductor pattern, a wiring pattern, or the like.

The positive electrode terminal 30 and the negative electrode terminal 40 are disposed on the first side 20a side extending in the first direction D1 (X-direction) of the multilayer substrate 20. The output terminal 50 is disposed on a second side 20b side of the multilayer substrate 20 facing the first side 20a in a second direction D2 (Y-direction). Each of the positive electrode terminal 30, the negative electrode terminal 40, and the output terminal 50 may be integrally molded by a metal plate of copper, a copper alloy, or the like.

The positive electrode terminal 30 may be referred to as a P terminal or an input terminal. The negative electrode terminal 40 may be referred to as an N terminal or an output terminal. The output terminal 50 may be referred to as an M terminal or an intermediate terminal.

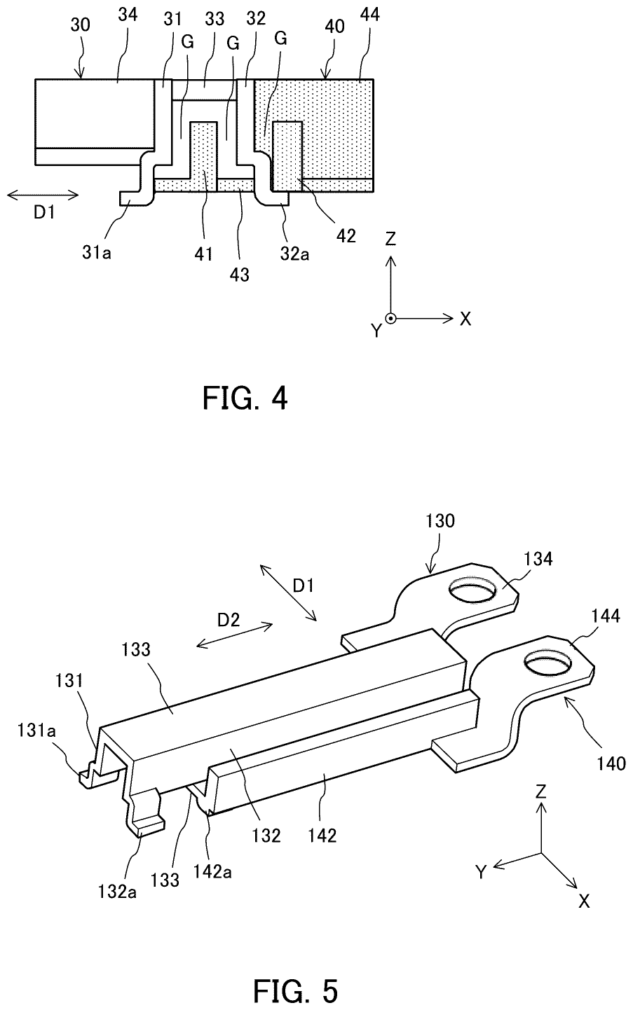

As illustrated in FIGS. 2 to 4, the positive electrode terminal 30 and the negative electrode terminal 40 include first rising portions 31 and 41, second rising portions 32 and 42, joining portions 33 and 43, and external connection portions 34 and 44. In FIG. 4, only the negative electrode terminal 40 is indicated by a halftone dot pattern in order to easily distinguish the positive electrode terminal 30 and the negative electrode terminal 40.

The first rising portions 31 and 41 and the second rising portions 32 and 42 extend in a direction (Z-direction) intersecting the mounting surface (upper surface) of the semiconductor element 10 in the multilayer substrate 20. For example, end portions of the first rising portions 31 and 41 and the second rising portions 32 and 42 on the Y-direction negative side (that is, the end portion on the first side 20a side of the multilayer substrate 20) are supported by the joining portions 33 and 43 which will be described later, and the first rising portions 31 and 41 and the second rising portions 32 and 42 extend in the second direction D2 (Y-direction positive side) toward the second side 20b of the multilayer substrate 20. As described above, the first rising portions 31 and 41 and the second rising portions 32 and 42 extend in the Y-direction and the Z-direction. Since the first rising portions 31 and 41 and the second rising portions 32 and 42 extend in the Z-direction, the first rising portions 31 and 41 and the second rising portions 32 and 42 can be referred to as vertical portions. However, the first rising portions 31 and 41 and the second rising portions 32 and 42 may extend in a direction different from the Z-direction (direction intersecting the XY plane) and the Y-direction.

The first rising portion 31 of the positive electrode terminal 30, the first rising portion 41 of the negative electrode terminal 40, the second rising portion 32 of the positive electrode terminal 30, and the second rising portion 42 of the negative electrode terminal 40 are located to be arranged on the X-direction positive side (first direction D1) in this order and face each other. These rising portions 31, 32, 41, and 42 may be arranged close to each other with a gap G (see FIGS. 2 and 4) of less than 10 mm such as around 1 mm, for example. These three gaps G may be the same or substantially the same.

The number of rising portions (the first rising portion 31 and the second rising portion 32) of the positive electrode terminal 30 and the number of rising portions (the first rising portion 41 and the second rising portion 42) of the negative electrode terminal 40, the rising portions being alternately arranged to face each other, only need to be three or more in total. Preferably, the number of rising portions alternately arranged in the positive electrode terminal 30 may be equal to the number of rising portions alternately arranged in the negative electrode terminal 40. More preferably, the number of first rising portions 31 and the second rising portions 32 of the positive electrode terminal 30 and the number of first rising portions 41 and the second rising portions 42 of the negative electrode terminal 40 may be four in total. The direction in which the rising portions (the first rising portion 31 and the second rising portion 32) of the positive electrode terminal 30 and the rising portions (the first rising portion 41 and the second rising portion 42) of the negative electrode terminal 40 face each other is not limited to the first direction D1 (X-direction), and may be the second direction D2 (Y-direction) or only needs to be a direction intersecting the Z-direction.

The first rising portions 31 and 41 and the second rising portions 32 and 42 include bonding target portions 31a, 32a, 41a, and 42a provided at end portions on the Y-direction positive side. The bonding target portions 31a and 32a of the positive electrode terminal 30 are bonded to the first circuit pattern 22a of the multilayer substrate 20 illustrated in FIG. 1 by, for example, a conductive bonding material (not illustrated) such as solder, ultrasonic bonding, or the like. The bonding target portions 41a and 42a of the negative electrode terminal 40 are bonded to the second circuit pattern 22b of the multilayer substrate 20 by, for example, a conductive bonding material (not illustrated) such as solder, ultrasonic bonding, or the like. The second circuit pattern 22b is located on the first side 20a side (the Y-direction negative side) of the first circuit pattern 22a. The first circuit pattern 22a and the second circuit pattern 22b are located in a region including the center portion of the multilayer substrate 20 in the X-direction. In FIG. 4, the bonding target portions 41a and 42a of the rising portions 41 and 42 of the negative electrode terminal 40 are hidden by the bonding target portions 31a and 32a of the rising portions 31 and 32 of the positive electrode terminal 30 and do not appear. That is, the bonding target portions 31a and 32a of the positive electrode terminal 30 and the bonding target portions 41a and 42a of the negative electrode terminal 40 have the same position in the X-direction. The positive electrode terminal 30 may be bonded to the second circuit pattern 22b, and the negative electrode terminal 40 may be bonded to the first circuit pattern 22a. In this case, since current paths which will be described later are opposite to each other, the configuration and arrangement of the semiconductor element 10 may be appropriately changed in accordance therewith.

The joining portion 33 of the positive electrode terminal 30 joins the first rising portion 31 and the second rising portion 32 to each other at the upper ends (that is, the end portions on the opposite side of the multilayer substrate 20, which is the Z-direction positive side) of the end portions of the first rising portion 31 and the end portion of the second rising portion 32 on the Y-direction negative side.

The joining portion 43 of the negative electrode terminal 40 joins the first rising portion 41 and the second rising portion 42 at the lower ends (that is, the end portion on the multilayer substrate 20 side which is the Z-direction negative side) of the end portions of the first rising portion 41 and the second rising portion 42 on the Y-direction negative side.

As described above, the first rising portion 31 and the second rising portion 32 of the positive electrode terminal 30 are supported at the upper end, and the first rising portion 41 and the second rising portion 42 of the negative electrode terminal 40 are supported at the lower end. The positive electrode terminal 30 may be supported at the lower end, or the negative electrode terminal 40 may be supported at the upper end.

The external connection portions 34 and 44 of the positive electrode terminal 30 and the negative electrode terminal 40 are fixed to the case 70 together with an external conductor by, for example, a screw and a nut in a screw hole portion. As described above, each of the positive electrode terminal 30 and the negative electrode terminal 40 is connected to the external conductor. The external connection portions 34 and 44 horizontally extend, for example, in a portion having a screw hole, and are bent downward from an end portion of this horizontal portion on the Y-direction positive side and further bent toward the Y-direction positive side. The external connection portions 34 and 44 may be integrally connected to the joining portions 33 and 43 at portions of the external connection portions 34 and 44 on the Y-direction positive side.

The case 70 has, for example, a quadrangular cylindrical shape with the Z-direction as a central axis, and accommodates the semiconductor element 10, the multilayer substrate 20, and the like in a state of being sealed with a sealing material (for example, epoxy resin, silicone gel, and the like) (not illustrated). The case 70 is formed, for example, using an insulating resin material such as poly phenylene sulfide (PPS) or poly amide (PA).

As illustrated in FIG. 1, the output terminal 50 includes bonding target portions 51 and 52 and external connection portions 53 and 54.

The bonding target portions 51 and 52 are provided at end portions of the output terminal 50 on the Y-direction negative side. The bonding target portion 51 is bonded to the third circuit pattern 22c, and the bonding target portion 52 is bonded to the fourth circuit pattern 22d by, for example, a conductive bonding material (not illustrated) such as solder, ultrasonic bonding, or the like. Here, the third circuit pattern 22c is located on one side (the X-direction negative side) of the first circuit pattern 22a in the first direction D1. The fourth circuit pattern 22d is located on the other side (the X-direction positive side) of the first circuit pattern 22a in the first direction D1. As described above, the first circuit pattern 22a is located between the third circuit pattern 22c and the fourth circuit pattern 22d in the X-direction. The third circuit pattern 22c and the fourth circuit pattern 22d may have a line-symmetric shape with respect to a symmetry axis (for example, an axis passing through the center of the multilayer substrate 20 in the X-direction) extending in the Y-direction.

The external connection portions 53 and 54 are fixed to the case 70 together with an external conductor by, for example, a screw and a nut in a screw hole portion. As described above, the output terminal 50 is connected to the external conductor. Although a current path is branched into the external connection portion 53 and the external connection portion 54, the output terminal 50 may include a single external connection portion.

As an example, 12 semiconductor elements 10 are mounted on the first circuit pattern 22a to which the positive electrode terminal 30 (bonding target portions 31a and 32a) is bonded. Among the semiconductor elements 10, six semiconductor elements 10 are mounted on an end portion of the first circuit pattern 22a on the third circuit pattern 22c side (the X-direction negative side) on a substantially straight line in the Y-direction, and are connected to the third circuit pattern 22c via the wiring W. The remaining six semiconductor elements 10 are mounted on an end portion of the first circuit pattern 22a on the fourth circuit pattern 22d side (the X-direction positive side) on a substantially straight line in the Y-direction, and are connected to the fourth circuit pattern 22d via the wiring W. As a result, a current can flow through the positive electrode terminal 30, the first circuit pattern 22a, the plurality of semiconductor elements 10, the third circuit pattern 22c or the fourth circuit pattern 22d, and the output terminal 50 in this order. The number of the plurality of semiconductor elements 10 mounted on the first circuit pattern 22a is not particularly limited, and the number of semiconductor elements 10 connected to the third circuit pattern 22c may be equal to the number of semiconductor elements 10 connected to the fourth circuit pattern 22d.

The fifth circuit pattern 22e is provided on the first side 20a side (that is, the Y-direction negative side) of the third circuit pattern 22c. The fifth circuit pattern 22e is connected to the third circuit pattern 22c by a plurality of wirings W. Six semiconductor elements 10 as an example of a plurality of pieces are mounted on the fifth circuit pattern 22e. The third circuit pattern 22c and the fifth circuit pattern 22e may be integrally provided.

The sixth circuit pattern 22f is provided on the first side 20a side (that is, the Y-direction negative side) of the fourth circuit pattern 22d. The sixth circuit pattern 22f is connected to the fourth circuit pattern 22d by a plurality of wirings W. Six semiconductor elements 10 as an example of a plurality of pieces are mounted on the sixth circuit pattern 22f. The fourth circuit pattern 22d and the sixth circuit pattern 22f may be integrally provided.

Here, the number of semiconductor elements 10 mounted on the fifth circuit pattern 22e and the number of semiconductor elements 10 mounted on the sixth circuit pattern 22f are not particularly limited. The number of semiconductor elements 10 mounted on the fifth circuit pattern 22e may be equal to the number of semiconductor elements 10 mounted on the sixth circuit pattern 22f.

The fifth circuit pattern 22e is located on one side (the X-direction negative side) in the first direction D1 with respect to the second circuit pattern 22b to which the negative electrode terminal 40 (bonding target portions 41a and 42a) is bonded. The sixth circuit pattern 22f is located on the other side (the X-direction positive side) of the second circuit pattern 22b in the first direction D1.

Each of the above-described six semiconductor elements 10 mounted on the fifth circuit pattern 22e and the above-described six semiconductor elements 10 mounted on the sixth circuit pattern 22f is connected to the second circuit pattern 22b via the wiring W. As a result, a current can flow through the output terminal 50, the third circuit pattern 22c or the fourth circuit pattern 22d, the fifth circuit pattern 22e or the sixth circuit pattern 22f, the semiconductor element 10, the second circuit pattern 22b, and the negative electrode terminal 40 in this order.

The control terminals 61 and 63 and the sensing terminal 64 are disposed on the X-direction negative side with respect to the multilayer substrate 20. The control terminals 62 and 65 are disposed on the X-direction positive side with respect to the multilayer substrate 20. The control terminals 61 and 62 are, for example, gate terminals, and the control terminals 63 and 65 are, for example, auxiliary terminals (auxiliary emitter terminal or auxiliary source terminal). The sensing terminal 64 is, for example, an auxiliary collector terminal or an auxiliary drain terminal.

The first to third relay portions R1 to R3 are provided between the six semiconductor elements 10 disposed at the end portion of the first circuit pattern 22a on the third circuit pattern 22c side (the X-direction negative side) and the six semiconductor elements 10 disposed at the end portion of the first circuit pattern 22a on the fourth circuit pattern 22d side (the X-direction positive side). The relay portions R1 to R3 may form a part of the circuit layer, similarly to the first circuit pattern 22a of the multilayer substrate 20.

Among the 12 semiconductor elements 10 mounted on the first circuit pattern 22a, each of the six semiconductor elements 10 on the Y-direction negative side is connected to the first relay portion R1 by a first control wiring W1 (wiring W). Among the 12 semiconductor elements 10 mounted on the first circuit pattern 22a, each of the six semiconductor elements 10 on the Y-direction positive side is connected to the second relay portion R2 by the first control wiring W1. The second relay portion R2 is arranged with the first relay portion R1 in the second direction D2 (Y-direction) with the third relay portion R3 interposed therebetween, and is located on the Y-direction positive side with respect to the first relay portion R1. Therefore, the length of the first control wiring W1 between each semiconductor element 10, and the first relay portion R1 or the second relay portion R2 is substantially the same. All the 12 semiconductor elements 10 may be connected to a single relay portion by the first control wiring W1, and may be connected to any one (closer relay portion) of a plurality of relay portions such as the first relay portion R1 and the second relay portion R2.

The seventh circuit pattern 22g extends in the second direction D2 (Y-direction) in a straight line on the X-direction negative side of the third circuit pattern 22c. Two second control wirings W2 (wirings W) extend in the X-direction with the same length and connect the first relay portion R1 or the second relay portion R2 with the seventh circuit pattern 22g. A third control wiring W3 (wiring W) extends in the X-direction and connects the seventh circuit pattern 22g and the control terminal 61.

The control terminal 62 is connected to the 12th circuit pattern 221 provided to surround both X-direction sides and the Y-direction positive side of the second circuit pattern 22b by a wiring W extending in the X-direction. The 12th circuit pattern 221 is connected to the plurality of semiconductor elements 10 mounted on the fifth circuit pattern 22e and the sixth circuit pattern 22f by a plurality of wirings W having the same length.

The control terminal 63 is connected to the eighth circuit pattern 22h extending in the second direction D2 (Y-direction) in a straight line on the X-direction negative side of the seventh circuit pattern 22g by the wiring W. The eighth circuit pattern 22h is connected to the second relay portion R2 by the wiring W. The second relay portion R2 is connected to the third circuit pattern 22c and the fourth circuit pattern 22d by the two wirings W having the same length.

The ninth circuit pattern 22i and the tenth circuit pattern 22j extending in the second direction D2 (Y-direction) in a straight line are provided on the X-direction positive side of the fourth circuit pattern 22d.

The 11th circuit pattern 22k extending in the first direction D1 (X-direction) in a straight line is provided at an end portion of the multilayer substrate 20 on the Y-direction positive side. The 11th circuit pattern 22k is connected to each of the sensing terminal 64 and the first circuit pattern 22a by the wiring W.

The 13th circuit pattern 22m extending in the second direction D2 (Y-direction) in a straight line is provided on the X-direction positive side of the sixth circuit pattern 22f. The 14th circuit pattern 22n extending in the first direction D1 (X-direction) in a straight line is provided at the end portion of the multilayer substrate 20 on the Y-direction negative side. The 13th circuit pattern 22m and the 14th circuit pattern 22n are connected by the wiring W. The 14th circuit pattern 22n is connected to the second circuit pattern 22b by the wiring W.

The temperature sensing terminals 66 and 67 are disposed on the X-direction negative side of the end portion of the multilayer substrate 20 on the Y-direction negative side, and are connected to the temperature sensing unit 68 by the wiring W. The temperature sensing unit 68 can include, for example, two circuit patterns forming a part of the circuit layer of the multilayer substrate 20 and a thermistor provided therebetween.

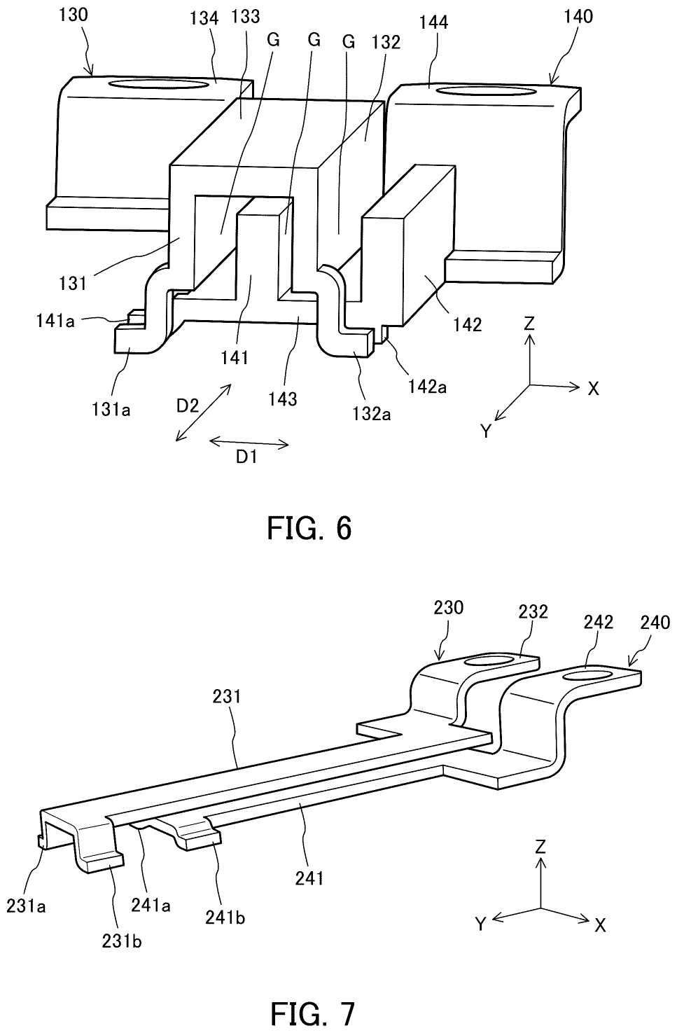

FIGS. 5 and 6 are a top perspective view and a left side perspective view illustrating a positive electrode terminal 130 and a negative electrode terminal 140 according to a modification example of the embodiment.

In the present modification example, the positive electrode terminal 130 can be made similar to the above-described positive electrode terminal 30 except that an upper end support portion 133 is provided instead of the joining portion 33. In the present modification example, the negative electrode terminal 140 can be made similar to the above-described negative electrode terminal 40 except that a lower end support portion 143 is provided instead of the joining portion 43. That is, first rising portions 131 and 141, second rising portions 132 and 142, and external connection portions 134 and 144 of the positive electrode terminal 130 and the negative electrode terminal 140 can be made similar to the first rising portions 31 and 41, the second rising portions 32 and 42, and the external connection portions 34 and 44 of the positive electrode terminal 30 and the negative electrode terminal 40.

Therefore, the first rising portions 131 and 141 and the second rising portions 132 and 142 include bonding target portions 131a, 132a, 141a, and 142a provided at end portions on the Y-direction positive side. The first rising portion 131 of the positive electrode terminal 130, the first rising portion 141 of the negative electrode terminal 140, the second rising portion 132 of the positive electrode terminal 130, and the second rising portion 142 of the negative electrode terminal 140 are located to be arranged on the X-direction positive side (first direction D1) in this order and face each other. That is, the rising portions (the first rising portion 131 and the second rising portion 132) of the positive electrode terminal 130 and the rising portions (the first rising portion 141 and the second rising portion 142) of the negative electrode terminal 140 are located to be alternately arranged. These rising portions 131, 132, 141, and 142 may be arranged close to each other with a gap G (see FIG. 6) of less than 10 mm such as around 1 mm, for example. Although FIG. 6 illustrates the lengths of the three gaps G to be different, this is because the end portion of the negative electrode terminal 140 on the Y-direction positive side is located on the Y-direction negative side of the end portion of the positive electrode terminal 130 on the Y-direction positive side, and actually, the three gaps G are the same or substantially the same.

The upper end support portion 133 of the positive electrode terminal 130 extends by the same length as the first rising portion 131 and the second rising portion 132 in the second direction D2 (the Y-direction negative side), and supports the upper ends (that is, the end portions on the opposite side of the multilayer substrate 20, which is the Z-direction positive side) of the first rising portion 131 and the second rising portion 132. As a result, the upper end support portion 133 joins the first rising portion 131 and the second rising portion 132. The first rising portion 131 and the second rising portion 132 have a downward U-shaped plate shape together with the upper end support portion 133.

The lower end support portion 143 of the negative electrode terminal 140 extends by the same length as the first rising portion 141 and the second rising portion 142 in the second direction D2 (the Y-direction negative side), and supports the lower ends (that is, the end portions on the multilayer substrate 20 side, which is the Z-direction negative side) of the first rising portion 141 and the second rising portion 142. As a result, the lower end support portion 143 joins the first rising portion 141 and the second rising portion 142. The first rising portion 141 and the second rising portion 142 have an upward U-shaped plate shape together with the lower end support portion 143. The lower end support portion 143 extends toward the X-direction negative side with respect to the first rising portion 141. The bonding target portion 141a of the first rising portion 141 of the negative electrode terminal 140 is located on the X-direction negative side with respect to the first rising portion 141. Therefore, the bonding target portion 141a of the first rising portion 141 can also be regarded as being provided in the lower end support portion 143.

As described above, in the present embodiment, the positive electrode terminal 30 and the negative electrode terminal 40 (alternatively, the positive electrode terminal 130 and the negative electrode terminal 140 in the modification example) include the first rising portions 31 and 41 and the second rising portions 32 and 42 (alternatively, the first rising portions 131 and 141 and the second rising portions 132 and 142 in the modification example) located to be arranged and face each other in the X-direction.

On the other hand, a positive electrode terminal 230 and a negative electrode terminal 240 in a comparative example illustrated in FIG. 7 include horizontal portions 231 and 241 extending in the XY-directions, and these horizontal portions 231 and 241 are located to face each other vertically (Z-direction). The horizontal portions 231 and 241 are provided with bonding target portions 231a, 231b, 241a, and 241b to be bonded to a substrate (not illustrated) at an end portion on the Y-direction positive side. The positive electrode terminal 230 and the negative electrode terminal 240 include external connection portions 232 and 242 connected to external conductors.

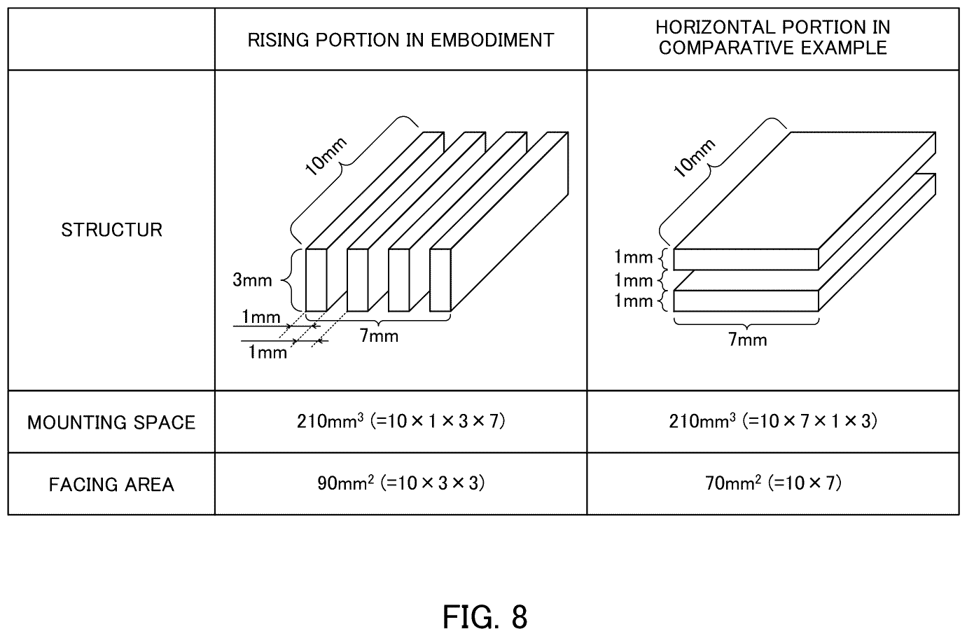

FIG. 8 schematically illustrates a structure of a case where four first rising portions 31 and 41 and four second rising portions 32 and 42 in the embodiment are alternately arranged to face each other in the X-direction and a case where two horizontal portions 231 and 241 in the comparative example are arranged to face each other in the Z-direction. In the embodiment, a case where four plates having a width of 1 mm (X-direction), a height of 3 mm (Z-direction), and a depth of 10 mm (Y-direction) are arranged with a gap of 1 mm has been described as an example. In the comparative example, a case where two plates having a width of 7 mm (X-direction), a height of 1 mm (Z-direction), and a depth of 10 mm (Y-direction) are arranged with a gap of 1 mm has been described as an example.

In both the embodiment and the comparative example, the same mounting area (70 mm²), the same height (3 mm), and the same mounting space (210 mm³) are provided, but the facing area is 90 mm² in total in the embodiment, which is a value of about 128% of 70 mm² in total in the comparative example. Therefore, the mutual inductance can be further increased in the embodiment. In other words, in a case where the same facing area is obtained in the embodiment and the comparative example, the mounting area and the height of the positive electrode terminal 30 and the negative electrode terminal 40 in the embodiment in plan view can be made smaller than the mounting area of the positive electrode terminal 230 and the negative electrode terminal 240 in the comparative example in plan view.

In the present embodiment described above, the semiconductor device 1 includes the semiconductor element 10, the multilayer substrate 20 (an example of the substrate) on which the semiconductor element 10 is mounted, and the positive electrode terminal 30 and the negative electrode terminal 40 disposed on the first side 20a side extending in the first direction D1 (X-direction) of the multilayer substrate 20. Each of the positive electrode terminal 30 and the negative electrode terminal 40 includes the first rising portions 31 and 41 and the second rising portions 32 and 42 (examples of the rising portions) extending in the direction (Z-direction) intersecting the mounting surface of the semiconductor element 10 in the multilayer substrate 20. The first rising portion 31 and the second rising portion 32 of the positive electrode terminal 30 and the first rising portion 41 and the second rising portion 42 of the negative electrode terminal 40, four in total (the example of three or more pieces in total), are located to be arranged and face each other alternately opposed to each other.

As a result, by increasing the facing area between the positive electrode terminal 30 and the negative electrode terminal 40, it is possible to increase the mutual inductance at the time of switching of the semiconductor element 10. In addition, since the first rising portion 31 and the second rising portion 32 of the positive electrode terminal 30 and the first rising portion 41 and the second rising portion 42 of the negative electrode terminal 40 extend in the Z-direction and alternately face each other in the horizontal direction, it is possible to increase the facing area and eventually the mutual inductance with a small mounting area (mounting space) as compared with an aspect in which the first rising portion 31 and the second rising portion 32 of the positive electrode terminal 30 and the first rising portion 41 and the second rising portion 42 of the negative electrode terminal 40 face each other in the Z-direction as in the horizontal portions 231 and 241 of the positive electrode terminal 230 and the negative electrode terminal 240 in the comparative example. Thus, according to the present embodiment, it is possible to increase the mutual inductance while suppressing an increase in the mounting area of the positive electrode terminal 30 and the negative electrode terminal 40. As a result, it is possible to suppress generation of a surge voltage (di/dt surge noise) at the time of switching (for example, at the time of high-speed switching in a case where the semiconductor element 10 is a SiC module or the like). In addition, by suppressing an increase in the mounting area of the positive electrode terminal 30 and the negative electrode terminal 40, it is possible to increase the degree of freedom in pattern layout of the circuit layer of the multilayer substrate 20 and to enable mounting of the semiconductor element 10 with higher rating. Furthermore, since the first rising portion 31 and the second rising portion 32 of the positive electrode terminal 30 and the first rising portion 41 and the second rising portion 42 of the negative electrode terminal 40 alternately face each other in the horizontal direction, it is possible to reduce bending of the positive electrode terminal 30 and the negative electrode terminal 40 as compared with an aspect in which the first rising portion 31 and the second rising portion 32 of the positive electrode terminal 30 and the first rising portion 41 and the second rising portion 42 of the negative electrode terminal 40 face each other in the Z-direction as in the horizontal portions 231 and 241 of the positive electrode terminal 230 and the negative electrode terminal 240 in the comparative example. Thus, it is also possible to secure an insulation distance between the positive electrode terminal 30 and the negative electrode terminal 40 and to prevent an occurrence of a situation in which a load is applied to a bonding portion between the positive electrode terminal 30 and the negative electrode terminal 40, and the multilayer substrate 20. In addition, since the generation of the surge voltage is suppressed by increasing the mutual inductance, it is possible to avoid an increase in the cross-sectional area or an increase in the terminal wiring length, unlike an aspect in which the generation of the surge voltage is suppressed by reducing the self-inductance, that is, an aspect in which the cross-sectional area (area perpendicular to the current path) of the positive electrode terminal 30 and the negative electrode terminal 40 is increased or the terminal wiring length is increased.

In the present embodiment, the first rising portion 31 and the second rising portion 32 of the positive electrode terminal 30 and the first rising portion 41 and the second rising portion 42 of the negative electrode terminal 40 are located to be arranged in the first direction D1 (X-direction).

As a result, as compared with an aspect in which the first rising portion 31 and the second rising portion 32 of the positive electrode terminal 30 and the first rising portion 41 and the second rising portion 42 of the negative electrode terminal 40 are arranged in the second direction D2 (Y-direction), it is possible to narrow the width of the mounting area of the positive electrode terminal 30 and the negative electrode terminal 40 in the X-direction. Thus, the semiconductor element 10 and the circuit layer can be easily disposed on both sides of the first rising portions 31 and 41 and the second rising portions 32 and 42 in the X-direction.

In the present embodiment, each of the plurality of rising portions (the first rising portion 31 and the second rising portion 32) of the positive electrode terminal 30 and the plurality of rising portions (the first rising portion 41 and the second rising portion 42) of the negative electrode terminal 40 is supported at the end portion on the first side 20a side of the multilayer substrate 20, and extends in the second direction D2 (Y-direction) toward the second side 20b of the multilayer substrate 20 facing the first side 20a in the second direction D2 (Y-direction).

As a result, the first rising portion 31 and the second rising portion 32 of the positive electrode terminal 30 and the first rising portion 41 and the second rising portion 42 of the negative electrode terminal 40 can be caused to face each other in the X-direction with a simple configuration. Since it is possible to narrow the width of the mounting area of the positive electrode terminal 30 and the negative electrode terminal 40 in the X-direction, the semiconductor element 10 and the circuit layer can be easily disposed on both sides of the first rising portions 31 and 41 and the second rising portions 32 and 42 in the X-direction. Further, in a case where members such as the lower end support portion 143 and the upper end support portion 133 in the modification example are omitted below the second rising portion 32 of the positive electrode terminal 30 or above the first rising portion 41 of the negative electrode terminal 40, it is possible to more extend the second rising portion 32 downward or more extend the first rising portion 41 upward.

In the present embodiment and the modification example thereof, the first rising portion 31 or 131 and the second rising portion 32 or 132, which are an example of one of the plurality of rising portions (the first rising portion 31 or 131 and the second rising portion 32 or 132) of the positive electrode terminal 30 or 130 and the plurality of rising portions (the first rising portion 41 or 141 and the second rising portion 42 or 142) of the negative electrode terminal 40 or 140, are supported at the upper end (the end portion on the opposite side of the multilayer substrate 20 in the direction (Z-direction) intersecting the mounting surface (upper surface) of the multilayer substrate 20) by, for example, the joining portion 33 or the upper end support portion 133, and the first rising portion 41 or 141 and the second rising portion 42 or 142, which are an example of the other rising portion, are supported at the lower end (the end portion on the multilayer substrate 20 side in the intersecting direction (Z-direction)) by, for example, the joining portion 43 or the lower end support portion 143.

As a result, it is possible to stably hold the plurality of rising portions (the first rising portion 31 or 131 and the second rising portion 32 or 132) of the positive electrode terminal 30 or 130 and the plurality of rising portions (the first rising portion 41 or 141 and the second rising portion 42 or 142) of the negative electrode terminal 40 or 140 at positions where the plurality of rising portions do not interfere with each other, and it is possible to reduce warping of the positive electrode terminal 30 or 130 and the negative electrode terminal 40 or 140.

In the modification example (FIGS. 5 and 6) of the present embodiment, the two one rising portions (the first rising portion 131 and the second rising portion 132) form a U-plate shape together with the upper end support portion 133 located at the upper end, and the two other rising portions (the first rising portion 141 and the second rising portion 142) form a U-plate shape together with the lower end support portion 143 located at the lower end.

As a result, it is possible to further stably hold the plurality of rising portions (the first rising portion 131 and the second rising portion 132) of the positive electrode terminal 130 and the plurality of rising portions (the first rising portion 141 and the second rising portion 142) of the negative electrode terminal 140, and it is possible to further reduce warping of the positive electrode terminal 130 and the negative electrode terminal 140. In addition, it is possible to increase the mutual inductance between the upper end support portion 133 and the rising portion of the negative electrode terminal 140 (the upper end of the first rising portion 141) and between the lower end support portion 143 and the rising portion of the positive electrode terminal 130 (the lower end of the second rising portion 132).

In the present embodiment, the positive electrode terminal 30 (an example of one of the positive electrode terminal 30 and the negative electrode terminal 40) is bonded to the first circuit pattern 22a of the multilayer substrate 20, and the negative electrode terminal 40 (an example of the other terminal) is bonded to the second circuit pattern 22b located on the first side 20a side of the first circuit pattern 22a.

As a result, it is possible to dispose the positive electrode terminal 30 and the negative electrode terminal 40 to extend in the Y-direction, and to narrow the width of the mounting area of the positive electrode terminal 30 and the negative electrode terminal 40 in the X-direction. Thus, the semiconductor element 10 and the circuit layer can be easily disposed on both sides of the first rising portions 31 and 41 and the second rising portions 32 and 42 in the X-direction.

In the present embodiment, the semiconductor device 1 includes the output terminal 50 disposed on the second side 20b side of the multilayer substrate 20 facing the first side 20a of the multilayer substrate 20 in the second direction D2 (Y-direction). The output terminal 50 is bonded to the third circuit pattern 22c located on one side (the X-direction negative side) of the first circuit pattern 22a in the first direction D1 and the fourth circuit pattern 22d located on the other side (X-direction positive side) of the first circuit pattern 22a in the first direction D1.

As a result, it is possible to make the current path parallel to the third circuit pattern 22c and the fourth circuit pattern 22d, and to suppress the generation of the surge voltage. Further, it is possible to dispose the semiconductor element 10 and the circuit layer on both sides in the X-direction of the first circuit pattern 22a to which the positive electrode terminal 30 is bonded.

In the present embodiment, the semiconductor device 1 includes the plurality of semiconductor elements 10 mounted on the first circuit pattern 22a, and in the plurality of semiconductor elements 10, the number of semiconductor elements 10 connected to the third circuit pattern 22c is equal to the number of semiconductor elements 10 connected to the fourth circuit pattern 22d (for example, each six).

As a result, it is possible to cause a current to uniformly flow on both sides (the third circuit pattern 22c and the fourth circuit pattern 22d) in the X-direction of the first circuit pattern 22a to which the positive electrode terminal 30 is bonded.

In the present embodiment, the semiconductor device 1 includes the plurality of semiconductor elements 10 mounted on the fifth circuit pattern 22e located on the first side 20a side of the third circuit pattern 22c, and the plurality of semiconductor elements 10 mounted on the sixth circuit pattern 22f located on the first side 20a side of the fourth circuit pattern 22d. The number of semiconductor elements 10 mounted on the fifth circuit pattern 22e is equal to the number of semiconductor elements 10 mounted on the sixth circuit pattern 22f (for example, each six).

As a result, it is possible to make the current path parallel to the fifth circuit pattern 22e and the sixth circuit pattern 22f, and make the plurality of semiconductor elements 10 parallel to each other, and it is possible to suppress the generation of the surge voltage. In addition, it is possible to cause the current to uniformly flow through the fifth circuit pattern 22e and the sixth circuit pattern 22f.

In the present embodiment, the fifth circuit pattern 22e is located on one side (the X-direction negative side) of the second circuit pattern 22b in the first direction D1, and the sixth circuit pattern 22f is located on the other side (the X-direction positive side) of the second circuit pattern 22b in the first direction D1. Each of the plurality of semiconductor elements 10 mounted on the fifth circuit pattern 22e and the plurality of semiconductor elements 10 mounted on the sixth circuit pattern 22f is connected to the second circuit pattern 22b.

As a result, it is possible to cause a current to uniformly flow through the second circuit pattern 22b on both sides (the fifth circuit pattern 22e and the sixth circuit pattern 22f) in the X-direction of the second circuit pattern 22b to which the negative electrode terminal 40 is bonded.

In the present embodiment, the semiconductor device 1 includes the control terminal 61 and the plurality of control wirings (wirings W). The plurality of control wirings connect the plurality of semiconductor elements 10 mounted on the first circuit pattern 22a and the control terminal 61. The plurality of control wirings include a plurality of first control wirings W1 that connect the plurality of semiconductor elements 10 and one or more relay portions R1 and R2 provided in the first circuit pattern 22a.

As a result, it is possible to bring the lengths of the plurality of first control wirings W1 that connect the plurality of semiconductor elements 10 and the relay portions R1 and R2 close to the same length. Thus, it is possible to perform control by bringing a gate delay time or the like of the plurality of semiconductor elements 10 close to a constant value.

In the present embodiment, the plurality of semiconductor elements 10 (the number of semiconductor elements connected to the third circuit pattern 22c by the wiring W is equal to the number of semiconductor elements connected to the fourth circuit pattern 22d by the wiring W) mounted on the first circuit pattern 22a are connected to any one of the plurality of relay portions R1 and R2 located to be arranged in the second direction D2 (Y-direction).

As a result, by the first control wiring W1, it is possible to connect the semiconductor element 10 to the closer one in accordance with the position of the semiconductor element 10 in the Y-direction among the first relay portion R1 and the second relay portion R2 disposed between the semiconductor element 10 that is connected to the third circuit pattern 22c by the wiring W and is arranged in the second direction D2 and the semiconductor element 10 that is connected to the fourth circuit pattern 22d by the wiring W and is arranged in the second direction D2. Therefore, it is possible to bring the lengths of the plurality of first control wirings W1 that connect the plurality of semiconductor elements 10 and the relay portions R1 and R2 closer to the same length.

In the present embodiment, the plurality of control wirings include a plurality of second control wirings W2 and a plurality of third control wirings W3. The plurality of second control wirings W2 connect the plurality of relay portions (the first relay portion R1 and the second relay portion R2) located to be arranged in the second direction D2 (Y-direction) and the seventh circuit pattern 22g extending in the second direction D2 (Y-direction). The third control wiring W3 connects the seventh circuit pattern 22g and the control terminal 61.

As a result, it is possible to bring not only the lengths of the plurality of first control wirings W1 that connect the semiconductor element 10 and the plurality of relay portions (the first relay portion R1 and the second relay portion R2) but also the lengths of the plurality of second control wirings W2 that connect the plurality of relay portions and the seventh circuit pattern 22g extending in the second direction D2 (Y-direction) close to the same length.

Hereinafter, the invention described in the claims of the originally filed application will be additionally described.

### <Supplementary Note 1>

A semiconductor device including:
a semiconductor element;
a substrate on which the semiconductor element is mounted; and
a positive electrode terminal and a negative electrode terminal disposed on a first side side extending in a first direction of the substrate,
in which each of the positive electrode terminal and the negative electrode terminal has a rising portion extending in a direction intersecting a mounting surface of the semiconductor element on the substrate, and
three or more rising portions of the positive electrode terminal in total and three or more rising portions of the negative electrode terminal in total are located to be arranged and face each other.

### <Supplementary Note 2>

The semiconductor device according to Supplementary Note 1,
in which the rising portion of the positive electrode terminal and the rising portion of the negative electrode terminal are located to be arranged in the first direction.

### <Supplementary Note 3>

The semiconductor device according to Supplementary Note 2,
in which each of a plurality of the rising portions of the positive electrode terminal and a plurality of the rising portions of the negative electrode terminal is supported at an end portion on the first side side, and extends in a second direction toward a second side of the substrate facing the first side in the second direction.

### <Supplementary Note 4>

The semiconductor device according to Supplementary Note 2,
in which either one of the plurality of the rising portions of the positive electrode terminal and the plurality of the rising portions of the negative electrode terminal is supported at an end portion on an opposite side of the substrate in the intersecting direction, and the other of the plurality of the rising portions is supported at an end portion on the substrate side in the intersecting direction.

### <Supplementary Note 5>

The semiconductor device according to Supplementary Note 4,
in which two of the one rising portions form a U-shaped plate shape together with a support portion located at end portions of the two one rising portions on the opposite side of the substrate in the intersecting direction, and
two of the other rising portions form a U-shaped plate shape together with a support portion located at end portions of the two other rising portions on the substrate side in the intersecting direction.

### <Supplementary Note 6>

The semiconductor device according to Supplementary Note 1,
in which one of the positive electrode terminal and the negative electrode terminal is bonded to a first circuit pattern of the substrate, and
the other of the positive electrode terminal and the negative electrode terminal is bonded to a second circuit pattern of the substrate located on the first side side of the first circuit pattern.

### <Supplementary Note 7>

The semiconductor device according to Supplementary Note 6, further including:
an output terminal that is disposed on a second side side of the substrate and faces the first side of the substrate in a second direction,
in which the output terminal is bonded to a third circuit pattern of the substrate located on one side of the first circuit pattern in the first direction and a fourth circuit pattern of the substrate located on the other side of the first circuit pattern in the first direction.

### <Supplementary Note 8>

The semiconductor device according to Supplementary Note 7, further including:
a plurality of the semiconductor elements mounted on the first circuit pattern,
in which, in the plurality of the semiconductor elements, the number of the semiconductor elements connected to the third circuit pattern is equal to the number of the semiconductor elements connected to the fourth circuit pattern.

### <Supplementary Note 9>

The semiconductor device according to Supplementary Note 7, further including:
a plurality of the semiconductor elements mounted on a fifth circuit pattern of the substrate located on the first side side of the third circuit pattern; and
a plurality of the semiconductor elements mounted on a sixth circuit pattern of the substrate located on the first side side of the fourth circuit pattern,
in which the number of the semiconductor elements mounted on the fifth circuit pattern is equal to the number of the semiconductor elements mounted on the sixth circuit pattern.

### <Supplementary Note 10>

The semiconductor device according to Supplementary Note 9,
in which the fifth circuit pattern is located on one side of the second circuit pattern in the first direction,
the sixth circuit pattern is located on the other side of the second circuit pattern in the first direction, and
each of the plurality of the semiconductor elements mounted on the fifth circuit pattern and the plurality of the semiconductor elements mounted on the sixth circuit pattern is connected to the second circuit pattern.

### <Supplementary Note 11>

The semiconductor device according to Supplementary Note 8, further including:
a control terminal; and
a plurality of control wirings that connect the plurality of the semiconductor elements mounted on the first circuit pattern and the control terminal,
in which the plurality of control wirings include a plurality of first control wirings that connect the plurality of the semiconductor elements and one or more relay portions provided in the first circuit pattern.

### <Supplementary Note 12>

The semiconductor device according to Supplementary Note 11,
in which the plurality of the semiconductor elements mounted on the first circuit pattern are connected to any one of a plurality of the relay portions located to be arranged in the second direction.

### <Supplementary Note 13>

The semiconductor device according to Supplementary Note 12,
in which the plurality of control wirings include a plurality of second control wirings that connect the plurality of the relay portions located to be arranged in the second direction and a seventh circuit pattern of the substrate extending in the second direction, and a third control wiring that connects the seventh circuit pattern and the control terminal.

As described above, the present invention has an effect of increasing the mutual inductance while suppressing an increase in the mounting area of the positive electrode terminal and the negative electrode terminal, and is useful for a semiconductor device such as a power semiconductor device, for example.

What is claimed is:

1. A semiconductor device, comprising:
a substrate having a mounting surface;
a semiconductor element mounted on the mounting surface of the substrate; and
a positive electrode terminal and a negative electrode terminal disposed on the substrate, wherein
each of the positive electrode terminal and the negative electrode terminal has at least one rising portion, to thereby have a total of at least three rising portions, each extending in a plane that intersects the mounting surface of the semiconductor element, and
each of the at least one rising portion of the positive electrode terminal faces one of the at least one rising portion of the negative electrode terminal in a first direction.

2. The semiconductor device according to claim 1, wherein the rising portions of the positive electrode terminal and the rising portions of the negative electrode terminal are arranged one next to another in the first direction.

3. The semiconductor device according to claim 2, wherein each of the rising portions of the positive electrode terminal and the rising portions of the negative electrode terminal is of an elongated shape extending in a second direction perpendicular to the first direction, one end of said each rising portion being supported by the substrate.

4. The semiconductor device according to claim 2, wherein each of the rising portions of the positive electrode terminal and the negative electrode terminal has a first end and a second end opposite to each other in a third direction perpendicular to both the first and second directions, and
the rising portions of the positive electrode terminal have the first ends thereof supported by the substrate, and the rising portions of the negative electrode terminal have the second ends thereof supported by the substrate.

5. The semiconductor device according to claim 4, further comprising:
a first support portion joining the first ends of adjacent two of the rising portions of the positive electrode terminal, to thereby form a first U-shaped plate shape; and
a second support portion joining the second ends of adjacent two of the rising portions of the negative electrode terminal, to thereby form a second U-shaped plate shape.

6. The semiconductor device according to claim 1, wherein
the substrate has a first circuit pattern and a second circuit pattern disposed side by side in the second direction; and
the positive electrode terminal and the negative electrode terminal are respectively bonded to the first circuit pattern and the second circuit pattern.

7. The semiconductor device according to claim 6, wherein
the substrate has a first side and a second side opposite to each other in the second direction;
the positive electrode terminal and the negative electrode terminal are disposed at the first side of the substrate,
the first circuit pattern is disposed closer to the second side than to the first side,
the semiconductor device further includes an output terminal disposed at the second side of the substrate,
the substrate further includes a third circuit pattern and a fourth circuit pattern respectively on two sides of the first circuit pattern in the first direction, and
the output terminal is bonded to the third circuit pattern and the fourth circuit pattern.

8. The semiconductor device according to claim 7, wherein
the semiconductor element is provided in plurality,
the plurality of semiconductor elements includes a subset of the semiconductor elements mounted on the first circuit pattern, and
the subset of the semiconductor elements includes:
a first plurality of the semiconductor elements connected to the third circuit pattern,
a second plurality of the semiconductor elements connected to the fourth circuit pattern,
the first plurality and the second plurality being equal in number.

9. The semiconductor device according to claim 7, wherein
the substrate further includes a fifth circuit pattern and a sixth circuit pattern side by side respectively to the third circuit pattern and the fourth circuit pattern in the second direction,
the semiconductor element is provided in plurality, and
the plurality of semiconductor elements further includes:
a first plurality of the semiconductor elements mounted on the fifth circuit pattern; and
a second plurality of the semiconductor elements mounted on the sixth circuit pattern,
the first plurality and the second plurality being equal in number.

10. The semiconductor device according to claim 9, wherein
the fifth circuit pattern and the sixth circuit pattern are arranged respectively on two sides of the second circuit pattern in the first direction, and
each of the first plurality of semiconductor elements and the second plurality of semiconductor elements is connected to the second circuit pattern.

11. The semiconductor device according to claim 8, further comprising:
a control terminal;
a plurality of control wirings that respectively connect the subset of the semiconductor elements mounted on the first circuit pattern to the control terminal; and
at least one relay portion provided in the first circuit pattern, wherein
the plurality of control wirings include a plurality of first control wirings, each connecting one of the subset of the semiconductor elements mounted on the first circuit pattern to one of the at least one relay portion.

12. The semiconductor device according to claim 11, wherein
the at least one relay portion is provided in plurality, and the plurality of relay portions are aligned in the second direction,
each of the subset of the semiconductor elements mounted on the first circuit pattern is connected to one of the plurality of relay portions.

13. The semiconductor device according to claim 12, wherein
the substrate further includes a seventh circuit pattern extending in the second direction, and
the plurality of control wirings further includes:
a plurality of second control wirings that respectively connect the plurality of the relay portions to the seventh circuit pattern, and
a third control wiring that connects the seventh circuit pattern to the control terminal.
